(19) United States
(12) Patent Application Publication
(10) Pub. No.: US 2015/0075721 A1
(43) Pub. Date: Mar. 19, 2015

(54) SCREEN PRINTER AND COMPONENT MOUNTING LINE

(71) Applicant: PANASONIC CORPORATION, Osaka (JP)

(72) Inventors: Masayuki MANTANI, Yamanashi (JP); Toshiyuki MURAKAMI, Yamanashi (JP)

(21) Appl. No.: 14/486,084

(22) Filed: Sep. 15, 2014

(30) Foreign Application Priority Data
Sep. 19, 2013 (JP) 2013-193825
Nov. 18, 2013 (JP) 2013-237628

(51) Int. Cl. B32B 38/00; H05K 3/36; H05K 3/12; B32B 37/00; B32B 39/00

(52) U.S. Cl. CPC B32B 38/145; B32B 37/0046; B32B 39/00; H05K 3/1225; H05K 3/368; B32B 2307/202; B32B 2457/08
USPC 156/387; 101/123

(57) ABSTRACT

A screen printer includes: a mask having a first area formed with a first pattern and a second area formed with a second pattern; and a print head which forms a past printing on a board and is movable on the mask. When a paste print is formed using the first pattern, the print head moves from a start position located between the first area and the second area to the first area and then returns to the start position. When a paste print is formed using the second pattern, the print head moves from the start position to the second area and then returns to the start position.

### BACKGROUND

1. Technical Field

An aspect of the present invention relates to a screen printer for forming paste prints on boards using a mask formed with patterns. Another aspect of the invention relates to a component mounting line including the screen printer.

2. Background Art

There is a screen printer which performs, in parallel, screen printing operations for forming prints of paste such as solder on plural kinds of boards and successively supplies resulting boards to a two-lane component mounter (i.e., a component mounter equipped with two board conveying lanes) installed on a downstream side. JP-A-2009-070867 describes a screen equipped with two printing units. Each of the printing units includes a board holding unit and a mask and performs a screen printing operation. However, the screen printer becomes large, and cost is increased. JP-A-2011-143640 describes a screen printer including a single printing unit. The printing unit includes a mask having two pattern-formed areas each of which has a pattern formed therein. The screen printer further includes a board holding unit which holds a board and which is movable under the mask such that the board selectively contacts one of the two pattern-formed areas, whereby screen printing operations are performed using the respective patterns.

### SUMMARY

However, even in the above-described screen printer having two pattern-formed areas for a component mounter on a downstream process side, the screen printer requires two print heads: one for printing using a first pattern and the other for printing using a second pattern. Therefore, the structure of the screen printer becomes complex. Further, because of the two print heads, they waste a larger amount of paste than a screen printer with a single print head, and cost is increased in this respect.

An object of an aspect of the present invention is to provide a screen printer and a component mounting line which can perform printing operations on plural kinds of boards in parallel with a simple configuration while enabling reduction of the amount of paste wasted.

A first aspect of the present invention provides a screen printer including: a mask having a first area formed with a first pattern and a second area formed with a second pattern such that the first area and the second area are arranged in an arrangement direction; a board holding/moving mechanism which is movable in the arrangement direction under the mask, and which includes a board holding unit which holds a board so as to allow the board to selectively contact one of the first area and the second area by moving the board holding unit; and a print head which forms a past printing on the board through the mask, and which is movable on the mask in the arrangement direction, wherein when a paste print is formed on the board contacting the first area by using the first pattern, the print head moves in the arrangement direction from a start position located between the first area and the second area to the first area and then returns to the start position, and wherein when a paste print is formed on the board contacting the second area by using the second pattern, the print head moves in the arrangement direction from the start position to the second area and then returns to the start position.

A second aspect of the present invention provides the screen printer according to the first aspect further including: a board carry-in unit which is movable in the arrangement direction, and which transfers a board carried in from an upstream machine to the board holding/moving mechanism; and a board carry-out unit which is movable in the arrangement direction, and which receives the board on which a paste print has been formed by the print head from the board holding/moving mechanism and carries out the board to a downstream machine.

A third aspect of the present invention provides a component mounting line including: the screen printer according to the first or second aspect; and a component mounter which mounts a component on the board on which the paste print has been formed by the screen printer; wherein the component mounter includes a first board conveying lane and a second board conveying lane which are arranged in the arrangement direction, wherein the first board conveying lane carries in the board on which the paste print has been formed using the first pattern, and wherein the second conveying lane carries in the board on which the paste print has been formed using the second pattern.

A fourth aspect of the present invention provides the screen printer according to the first aspect further including: a board carry-in unit which is movable in the arrangement direction, and which transfers a board carried in from an upstream machine to the board holding/moving mechanism, and a board carry-out unit which receives the board on which the paste print has been formed by the print head from the board holding/moving mechanism, and which carries out the board to a downstream machine, wherein the board holding/moving mechanism is movable among a first position corresponding to the first area, a second position corresponding to the second area, and a third position which is located between the first position and the second position and at which the board is received from the board carry-in unit and transferred to the board carry-out unit.

A fifth aspect of the present invention provides a component mounting line including: the screen printer according to the first or fourth aspect; and a component mounter which mounts a component on the board on which the paste print has been formed by the screen printer; and wherein the component mounter includes a board conveying lane which carries in the board on which the paste print has been formed by using the first pattern and the board on which the paste print has been formed by using the second pattern.

In the aspects of the present invention, a paste print is formed as the print head reciprocates between the first or second area and the start position located between the first area and the second area on the mask. The single print head serves as both of a print head for printing with the first pattern and printing with the second pattern. Consequently, it is possible to perform, with a simple configuration, printing on plural kinds of boards in parallel so as to correspond with the two-lane component mounter installed on a downstream side. Furthermore, since the print head reciprocates, that is, moves from the start position located between the first area and the second area and returns to the original position (start position), residual paste can be used for the next printing irrespective of whether printing has been performed using the first pattern or the second pattern. Therefore, the amount of paste wasted is reduced and hence the cost can be reduced accordingly. Still further, since the paste on the mask is returned to a region between the first area and the second area on the mask when a printing operation has been completed, printing operations can be started immediately even if different kinds of boards are carried in in random order (i.e., a printing operation can be started immediately irrespective of whether a board contacts the first area or the second area).

### BRIEF DESCRIPTION OF THE DRAWINGS

FIG. 1 shows a general configuration of a component mounting line according to a first embodiment of the present invention;

FIG. 2 is a plan view of a screen printer which forms a part of the component mounting line according to the first embodiment;

FIG. 3 is a side view of the screen printer according to the first embodiment;

FIG. 4 is a plan view of a mask provided in the screen printer according to the first embodiment;

FIGS. 5A and 5B are partial sectional views of the screen printer according to the first embodiment;

FIG. 6 is a block diagram of a control system of the screen printer according to the first embodiment;

FIGS. 7A to 7E are operation diagrams of the screen printer according to the first embodiment;

FIGS. 8A and 8B are operation diagrams of the screen printer according to the first embodiment;

FIGS. 9A and 9B are operation diagrams of the screen printer according to the first embodiment;

FIGS. 10A and 10B are operation diagrams of the screen printer according to the first embodiment;

FIGS. 11A and 11B are operation diagrams of the screen printer according to the first embodiment;

FIG. 12 shows a general configuration of a component mounting line according to a second embodiment of the present invention;

FIG. 13 is a plan view of a screen printer which forms a part of the component mounting line according to the second embodiment;

FIGS. 14A to 14C are partial plan views of the screen printer according to the second embodiment; and

FIGS. 15A to 15F are operation diagrams of the screen printer according to the second embodiment.

### DETAILED DESCRIPTION

### First Embodiment

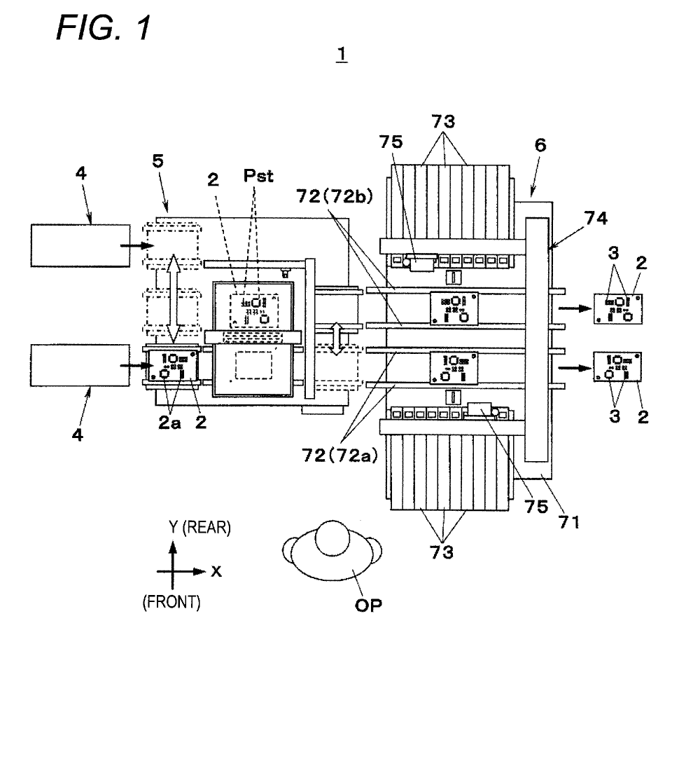

FIG. 1 shows a component mounting line 1 according to a first embodiment of the invention. The component mounting line 1, which is to manufacture component-mounted boards by mounting a component 3 on each board 2, includes a screen printer 5 for forming, by screen printing, paste layers Pst such as solder layers on electrodes 2a of each board 2 supplied from one of board supply units 4 and a component mounter 6 for mounting a component 3 on each board 2 on which paste layers Pst have been formed by the screen printer 5. In the component mounting line 1 according to the first embodiment, each board 2 flows left to right in FIG. 1 (in the left to right direction as viewed by an operator OP). This direction in a horizontal plane is defined as the positive X-axis direction. The direction that is perpendicular to the X-axis direction in the horizontal plane is defined as the Y-axis direction, and the top-bottom direction is defined as the Z-axis direction. In the first embodiment, the left side and the right side in the paper surface of FIG. 1 are the upstream (process) side and the downstream (process) side of the flow of a board 2, respectively.

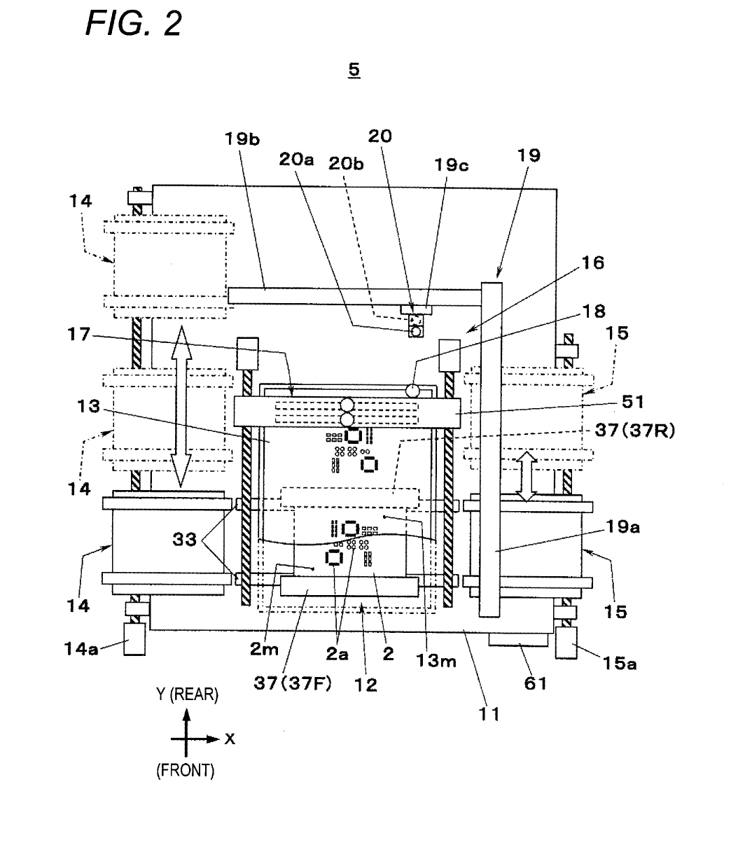

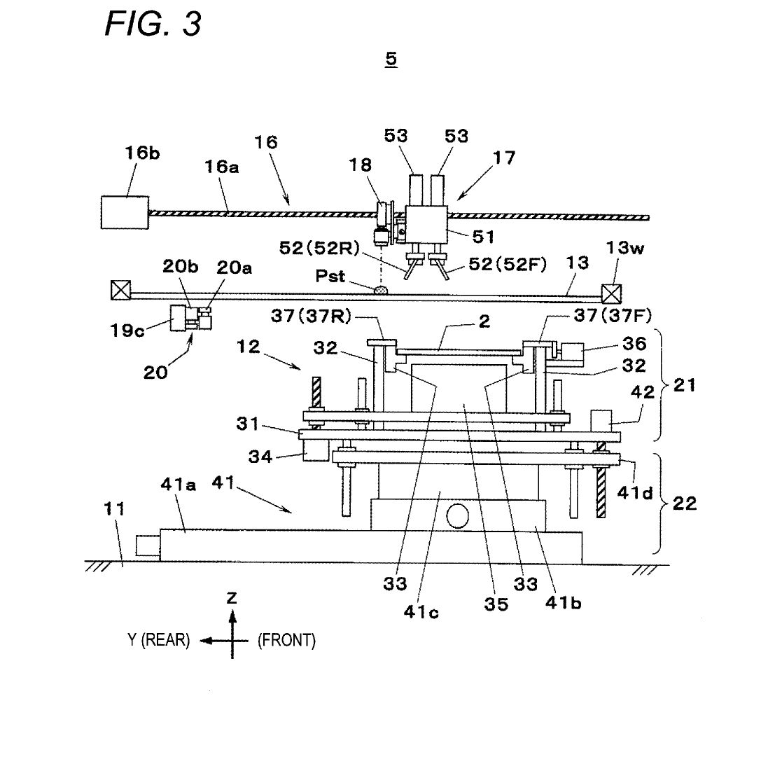

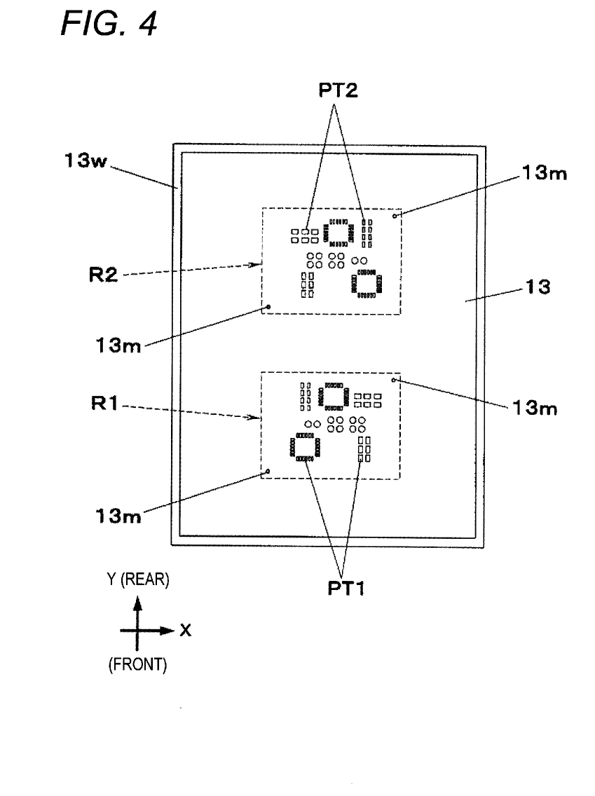

As shown in FIGS. 2 and 3, the screen printer 5 is equipped with a board holding/moving mechanism 12 on a stage 11. A mask 13 which is formed with patterns (a first pattern PT1 and a second pattern PT2 shown in FIG. 4) according to which prints should be formed on boards 2 is disposed over the board holding/moving mechanism 12. A carry-in conveyor 14 as a board carry-in unit for transferring a board 2 that is carried in from another, upstream machine (in the first embodiment, one of the board supply units 4) to the board holding/moving mechanism 12 is disposed on the stage 11 upstream of the board holding/moving mechanism 12 in the flow of a board 2 (i.e., on the left side in the paper surface of FIG. 1). A carry-out conveyor 15 as a board carry-out unit for receiving a board 2 from the board holding/moving mechanism 12 and carrying it out to another, downstream machine (in the first embodiment, component mounter 6) is disposed on the stage 11 downstream of the board holding/moving mechanism 12 in the flow of a board 2 (i.e., on the right side in the paper surface of FIG. 1). The screen printer 5 is also equipped with a print head 17 which is disposed over the mask 13 and moved by a print head moving mechanism 16, a paste supply syringe 18 which is integral with the print head 17, and a camera unit 20 which is disposed under the mask 13 and moved by a camera moving mechanism 19 in a horizontal plane.

As shown in FIG. 3, the board holding/moving mechanism 12 of the screen printer 5 includes a board holding unit 21 for holding a board 2 and a board holding unit moving mechanism 22 for moving the board holding unit 21. The board holding unit 21 is equipped with an elevation plate 31 which serves as a base, a pair of conveyors 33 (also see FIG. 2) which are attached to conveyor support members 32 which extend upward from the elevation plate 31, a support member 35 which is elevated and lowered over the elevation plate 31 by an elevation motor 34 which is attached to the elevation plate 31, and a pair of clampers 37 (also see FIG. 2) which are disposed over the respective conveyors 33 and opened and closed in the Y-axis direction by a clamper drive motor 36. The conveyors 33 convey, in the X-axis direction, a board 2 received from the carry-in conveyor 14 and positions it at a prescribed clamping position. The support member 35 supports, from below, the board 2 that has been positioned at the clamping position. The clampers 37 clamp, in the Y-axis direction, the board 2 being supported by the support member 35 when pressed against its side surfaces that are opposed to each other in the Y-axis direction. Of the two clampers 37 which are arranged in the Y-axis direction, the one located on the side of the operator OP (on the right side in the paper surface of FIG. 3 which is defined as the front side) is called a front clamper 37F and the other one opposite to the operator OP (on the left side in the paper surface of FIG. 3 which is defined as the rear side) is called a rear clamper 37R.

As shown in FIG. 3, the board holding unit moving mechanism 22 includes an XYθ table mechanism 41 for moving a base table 41d in a horizontal plane by causing a Y table 41a, an X table 41b, and a θ table 41c which are stacked on the stage 11 to move relative to each other and a second elevation motor 42 for elevating and lowering the elevation plate 31 (i.e., the entire board holding unit 21) relative to the base table 41d. The board holding unit moving mechanism 22 moves the board holding unit 21 which holds a board 2 (clamped by the dampers 37) in a horizontal plane by means of the XYθ table mechanism 41 and elevates and lowers it by means of the second elevation motor 42.

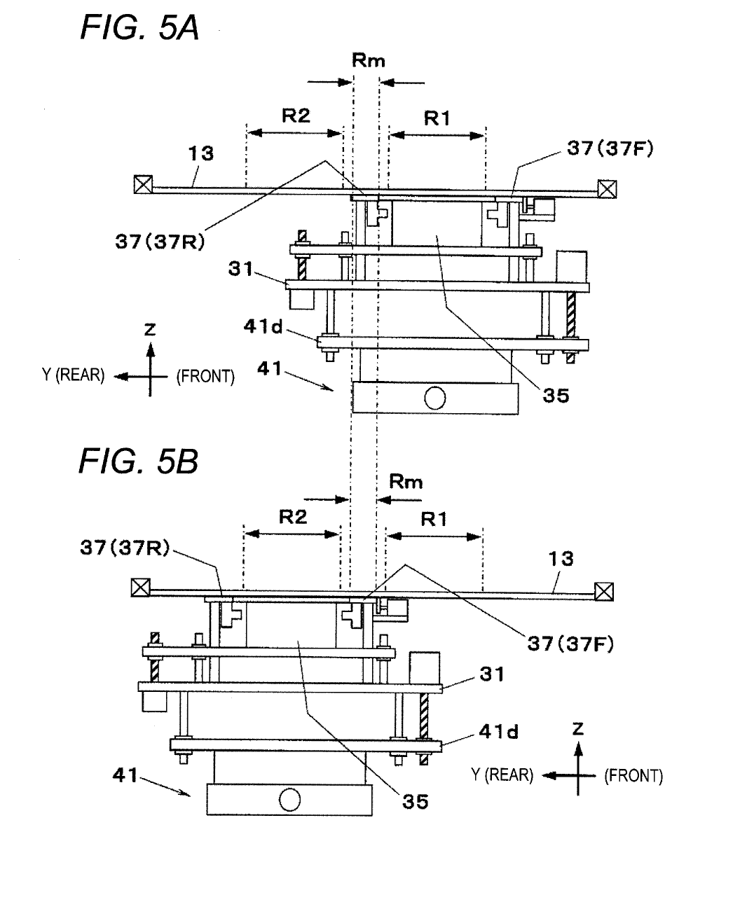

As shown in FIG. 4, the mask 13 has a flat, rectangular shape extending in the XY plane and its outer circumferential portion is supported by a frame member 13w. To enable screen printing for two kinds of boards 2, a first pattern-formed area (a first area) R1 in which a first pattern PT1 is formed and a second pattern-formed area (a second area) R2 in which a first pattern PT2 is formed are arranged in the Y-axis direction (an arrangement direction in a horizontal plane). Reference is also made to FIGS. 5A and 5B.

As shown in FIG. 2, the carry-in conveyor 14 can be moved by a carry-in conveyor moving mechanism 14a in the Y-axis direction (in the arrangement direction of the first pattern-formed area R1 and the second pattern-formed area R2 of the mask 13). As shown in FIG. 1, two board supply units 4 are disposed upstream of the screen printer 5 so as to be arranged in the Y-axis direction. Moved in the Y-axis direction by the carry-in conveyor moving mechanism 14a, the carry-in conveyor 14 can receive a board 2 from either of the two board supply units 4 and can transfer a board 2 to the board holding unit 21 whether it is located under the first pattern-formed area R1 or the second pattern-formed area R2. As shown in FIG. 2, the carry-out conveyor 15 can be moved by a carry-out conveyor moving mechanism 15a in the Y-axis direction, whereby the carry-out conveyor 15 can receive a board 2 from the board holding unit 21 whether it is located under the first pattern-formed area R1 or the second pattern-formed area R2.

As shown in FIG. 2, a pair of board-side marks 2m are formed in each board 2 at diagonal positions (only one pair of board-side marks 2m are shown in FIG. 2). A pair of mask-side marks 13m are formed in each of the first pattern-formed area R1 and the second pattern-formed area R2 of the mask 13 so as to correspond to the pair of board-side marks 2m (also see FIG. 4). If a board 2 being held by the board holding unit 21 is brought into contact with the mask 13 by elevating the board holding unit 21 by the second elevation motor 42 with the pair of board-side marks 2m registered with the pair of mask-side marks 13m of the first pattern-formed area R1 in a plan view, a state is established that the electrodes 2a on the board 2 are registered with the first pattern PT1 of the mask 13 (see FIG. 5A). Likewise, if a board 2 being held by the board holding unit 21 is brought into contact with the mask 13 by elevating the board holding unit 21 by the second elevation motor 42 with the pair of board-side marks 2m registered with the pair of mask-side marks 13m of the second pattern-formed area R2 in a plan view, a state is established that the electrodes 2a on the board 2 are registered with the second pattern PT2 of the mask 13 (see FIG. 5B). In this manner, in the first embodiment, the board holding/moving mechanism 12 moves the board holding unit 21 which is holding a board 2 and is disposed under the mask 13 so as to be movable in the arrangement direction (the arrangement direction of the first pattern-formed area R1 and the second pattern-formed area R2), whereby the board 2 is brought into contact with a selected one of the first pattern-formed area R1 and the second pattern-formed area R2.

As shown in FIGS. 5A and 5B, in the first embodiment, a region of the mask 13 where the rear clamper 37R comes into contact with the mask 13 when a board 2 is brought into contact with the first pattern-formed area R1 of the mask 13 and a region of the mask 13 where the front clamper 37F comes into contact with the mask 13 when a board 2 is brought into contact with the second pattern-formed area R2 of the mask 13 are in the same region Rm which is located between the first pattern-formed area R1 and the second pattern-formed area R2. Therefore, irrespective of whether a board 2 is brought in contact with the first pattern-formed area R1 or the second pattern-formed area R2, one clamper 37 (i.e., one of the front clamper 37F and the rear clamper 37R) is located in the region Rm between the first pattern-formed area R1 and the second pattern-formed area R2.

As shown in FIGS. 2 and 3, the print head 17 is equipped with two squeegees 52 which are disposed under a movable base 51 extending in the X-axis direction so as to be opposed to each other in the Y-axis direction. The print head moving mechanism 16 includes two print head moving ball screws 16a which extend in the Y-axis direction, penetrate through and are screwed into left and right end portions of the movable base 51, respectively, and two print head moving motors 16b for rotationally driving the two respective print head moving ball screws 16a. When the two print head moving ball screws 16a are rotated in synchronism with each other by the two print head moving motors 16b, the movable base 51 is moved in the Y-axis direction. The two squeegees 52 are elevated and lowered individually under the movable base 51 by respective squeegee elevation cylinders 53 which are provided on the movable base 51. Of the two squeegees 52 arranged in the Y-axis direction, the one located on the side of the operator OP (i.e., on the right side in the paper surface of FIG. 3) is called a front squeegee 52F and the other one opposite to the operator OP (on the left side in the paper surface of FIG. 3) is called a rear squeegee 52R.

As shown in FIGS. 2 and 3, the camera unit 20 is equipped with an upper field shooting camera 20a whose field of view is located above and a lower field shooting camera 20b whose field of view is located below. A camera unit moving mechanism 19 for moving the camera unit 20 in a horizontal plane is equipped with a Y-axis table 19a which extends in the Y-axis direction over the stage 11, an X-axis table 19b which extends in the X-axis direction and is moved on the Y-axis table 19a, and a movable plate 19c which is moved on the X-axis table 19b. Attached to the movable plate 19c, the camera unit 20 is moved in a horizontal plane when the X-axis table 19b is moved in the Y-axis direction relative to the Y-axis table 19a and the movable plate 19c is moved in the X-axis direction relative to the X-axis table 19b.

Stored with paste Pst inside, the paste supply syringe 18 discharges paste Pst downward. As shown in FIGS. 2 and 3, the paste supply syringe 18, which is attached to the movable base 51, can be moved in the Y-axis direction together with the squeegees 52 when the movable base 51 is moved in the Y-axis direction. The paste supply syringe 18 can also be moved in the X-axis direction on the movable base 51. The paste supply syringe 18 can move freely in a horizontal plane as a result of a movement of the movable base 51 in the Y-axis direction and a movement of the paste supply syringe 18 itself in the X-axis direction, whereby the paste supply syringe 18 can supply paste Pst to any region on the mask 13. The paste supply syringe 18 supplies paste Pst to the region Rm between the first pattern-formed area R1 and the second pattern-formed area R2 in a shape that extends in the extending direction (X-axis direction) of the squeegees 52.

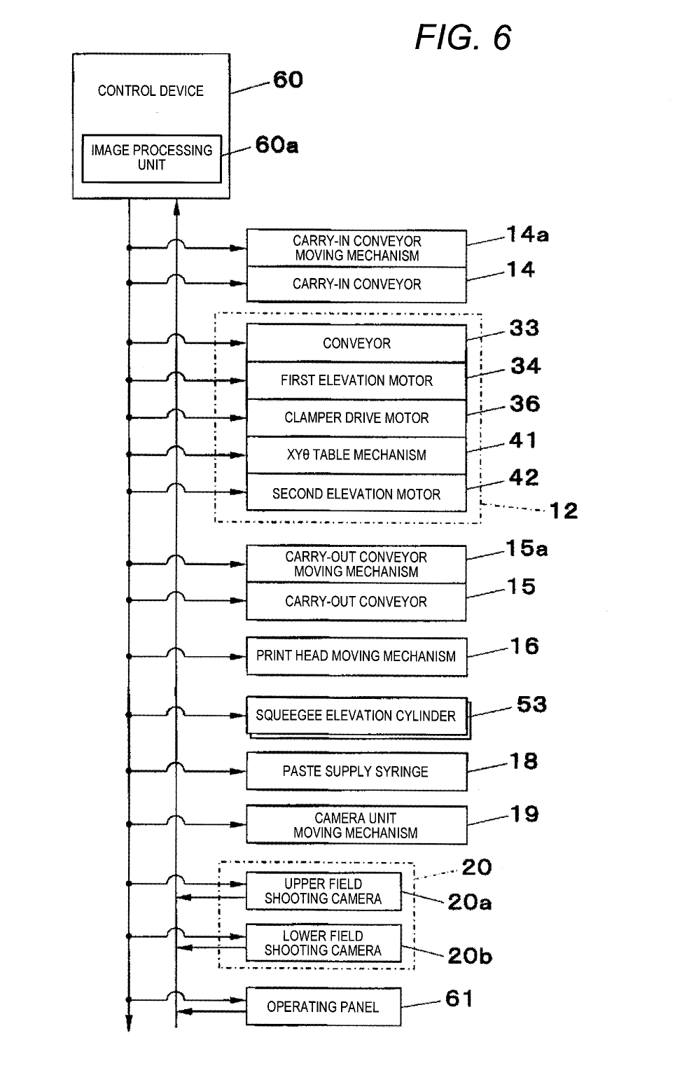

As shown in FIG. 6, a control device 60 of the screen printer 5 controls an operation of moving the carry-in conveyor 14 in the Y-axis direction which is performed by the carry-in conveyor moving mechanism 14a, an operation of carrying in a board 2 which is performed by the carry-in conveyor 14, an operation of moving a board 2 to the clamping position which is performed by the conveyors 33, an operation of elevating or lowering the support member 35 which is performed by the first elevation motor 34, an operation of causing the clampers 37 to clamp a board 2 which is performed by the clamper drive motor 36, an operation of moving the board holding unit 21 in a horizontal plane which is performed by the XYθ table mechanism 41, an operation of elevating or lowering the board holding unit 21 which is performed by the second elevation motor 42, an operation of moving the carry-out conveyor 15 in the Y-axis direction which is performed by the carry-out conveyor moving mechanism 15a, and a control of carrying out a board 2 which is performed by the carry-out conveyor 15. The control device 60 also controls an operation of moving the print head 17 in the Y-axis direction which is performed by the print head moving mechanism 16, an operation of elevating or lowering each squeegee 52 which is performed by the associated squeegee elevation cylinder 53, an operation of discharging paste Pst which is performed by the paste supply syringe 18, and an operation of moving the camera unit 20 in a horizontal plane which is performed by the camera unit moving mechanism 19.

Referring to FIG. 6, the upper field shooting camera 20a shoots the mask-side marks 13m formed in the first pattern-formed area R1 of the mask 13 and mask-side marks 13m formed in the second pattern-formed area R1 of the mask 13 under the control of the control device 60. The lower field shooting camera 20b shoots the board-side marks 2m of a board 2 which is being held by the board holding unit 21, under the control of the control device 60. Both of image data taken by the upper field shooting camera 20a and image data taken by the lower field shooting camera 20b are input to the control device 60 and subjected to image processing in an image processing unit of the control device 60. The control device 60 calculates positions of the respective mask-side marks 13m and positions of the respective board-side marks 2m on the basis of resulting images (shooting results) of the mask-side marks 13m and the board-side marks 2m.

As shown in FIG. 2, the front side (opposed to the operator OP) of the stage 11 is provided with an operating panel 61 with a display device to be manipulated by the operator OP. The operating panel 61 is connected to the control device 60 (see FIG. 6). Through the operating panel 61, the operator OP can perform every manipulation relating to the screen printer 5 and acquire various kinds of information relating to the screen printer 5.

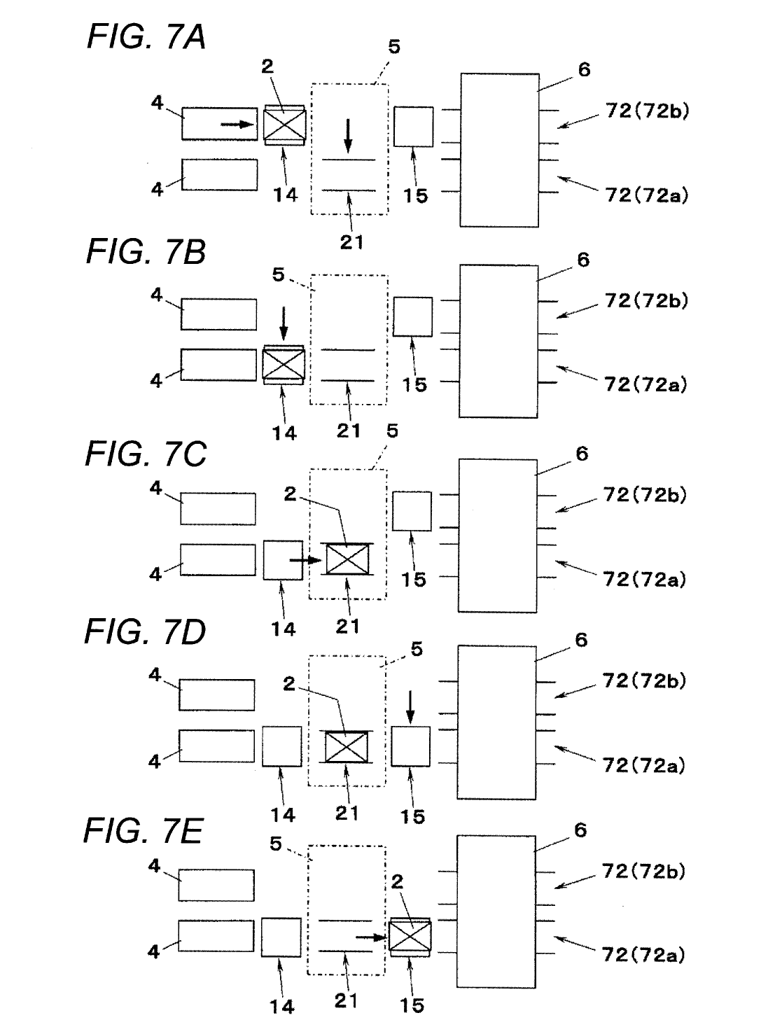

Next, a procedure according which the screen printer 5 performs a screen printing operation will be described with reference to FIGS. 7A to 11B. When a board 2 is to be output from one of the two board supply units 4, the control device 60 controls the carry-in conveyor moving mechanism 14a so that it moves the carry-in conveyor 14 to such a position that it is opposed to the board supply unit 4 that is going to output the board 2. The control device 60 causes the carry-in conveyor 14 to receive the board 2 that is output from the board supply unit 4, and controls the XYθ table mechanism 41 so that it moves the board holding unit 21 to a position (first position) that is located under the first pattern-formed area R1 or a position (second position) that is located under the second pattern-formed area R2 (see FIG. 7A). Whether the board holding unit 21 should be moved to the first position or the second position is determined by the kind of the board 2 (i.e., the arrangement of the electrodes 2a). The board holding unit 21 is moved to the first position if the arrangement of the electrodes 2a corresponds to the first pattern PT1, and to the second position if the arrangement of the electrodes 2a corresponds to the second pattern PT2. FIG. 7A shows a state in which the board holding unit 21 is placed at the first position.

When the board holding unit 21 has been moved to the first position or second position, the control device 60 controls the carry-in conveyor moving mechanism 14a so that it moves the carry-in conveyor 14 that has received the board 2 to a position corresponding to the first position or the second position (see FIG. 7B). More specifically, the carry-in conveyor 14 is moved to the position corresponding to the first position or second position if the board holding unit 21 is placed at the first position, and to the position corresponding to the second position if the board holding unit 21 is placed at the second position. FIG. 7B shows a state in which the carry-in conveyor 14 is placed at a position opposing the first position.

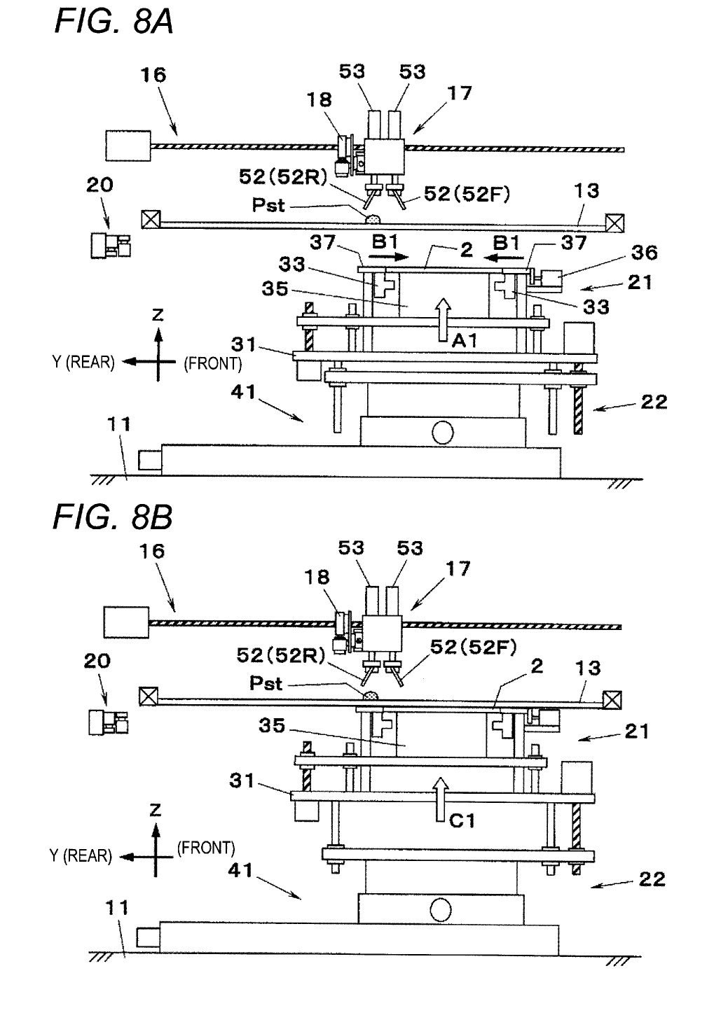

When the board holding unit 21 has been moved to the position corresponding to the first position or the second position, the control device 60 causes the carry-in conveyor 14 and the conveyors 33 of the board holding unit 21 to operate in link with each other so that the board 2 is put into the board holding unit 21 and positioned at the clamping position (see FIG. 7C). Then the control device 60 controls the first elevation motor 34 so that it elevates the support member 35 to support the board 2 from below and lift up the board 2 from the conveyors 33 (indicated by arrow A1 in FIG. 8A). In this state, the control device 60 controls the clamper drive motor 36 so that the clampers 37 clamp and hold the board 2 (indicated by arrows B1 in FIG. 8A).

When the board 2 has been held by the board holding unit 21, the control device 60 controls the camera unit moving mechanism 19 to move the camera unit 20 and causes the upper field shooting camera 20a to shoot the mask-side marks 13m. The upper field shooting camera 20a shoots the mask-side marks 13m of the first pattern-formed area R1 if the board 2 is to be brought into contact with the first pattern-formed area R1, and shoots the mask-side marks 13m of the second pattern-formed area R2 if the board 2 is to be brought into contact with the second pattern-formed area R2. When the mask-side marks 13m have been shot, the control device 60 causes the lower field shooting camera 20b to shoot the board-side marks 2m.

When the mask-side marks 13m and the board-side marks 2m have been shot, the control device 60 controls the board holding/moving mechanism 12 on the basis of positions of the mask-side marks 13m and the board-side marks 2m obtained by the shooting so that it brings the board 2 into contact with the mask 13 in the manner described above (indicated by arrow C1 in FIG. 8B). As a result, a state is established that the electrodes 2a of the board 2 are registered with the pattern (first pattern PT1 or second pattern PT2) of the mask 13 (see FIG. 8B).

When the board 2 has been brought into contact with the mask 13, the control device 60 checks, using a paste amount checking device (not shown), whether a sufficient amount of paste Pst exists in the region Rm (where the front clamper 37F or the rear clamper 37R is in contact with the mask 13) located between the first pattern-formed area R1 and the second pattern-formed area R2. If judging that a sufficient amount of paste Pst does not exist in the region Rm, the control device 60 causes the paste supply syringe 18 to supply paste Pst to the region Rm.

If judging that a sufficient amount of paste Pst exists in the region Rm between the first pattern-formed area R1 and the second pattern-formed area R2 (if paste Pst has just been supplied additionally from the paste supply syringe 18, a resulting amount of paste Pst is checked), the control device 60 causes the squeegees 52 to squeegee the paste Pst. In the squeegeeing, the control device 60 controls the print head moving mechanism 16 so that it moves the movable base 51 in the Y-axis direction and thereby reciprocates the print head 17 across (i.e., slides the squeegees 52 on) the first pattern-formed area R1 or the second pattern-formed area R2. As a result of the squeegeeing, the paste Pst is raked on the mask 13 and passes through the pattern of the mask 13. A paste print is thus formed on the board 2.

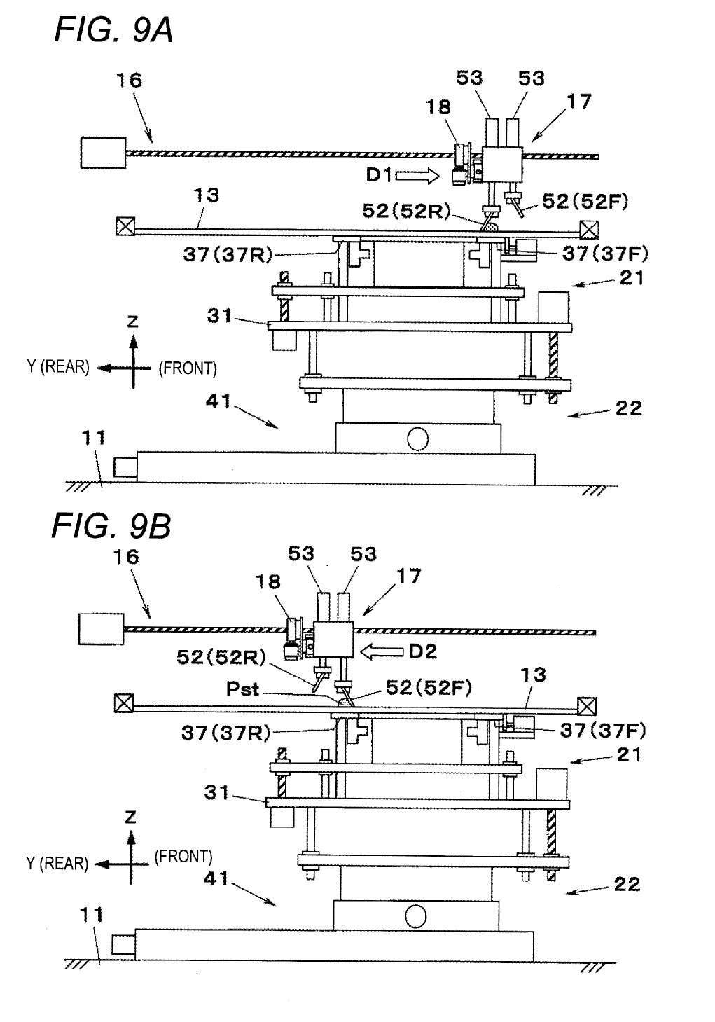

To form a paste print on the board 2 using the first pattern PT1 by squeegeeing, first, the rear squeegee 52R is lowered from over the region Rm between the first pattern-formed area R1 and the second pattern-formed area R2 until its bottom end comes into contact with the mask 13 in the region Rm where the rear clamper 37R is in contact with the mask 13. Then the rear squeegee 52R is moved forward (indicated by arrow D1 in FIG. 9A) with the above contact position (in the region Rm) as a movement start position. When the rear squeegee 52R has reached a position over the front clamper 37F as a result of sliding on the first pattern-formed area R1 of the mask 13, the rear squeegee 52R is elevated and the front squeegee 52F is lowered until its bottom end comes into contact with the mask 13 over the front clamper 37F is in contact with the mask 13. Then the front squeegee 52F is moved backward (indicated by arrow D2 in FIG. 9B) from the above contact position. When the front squeegee 52F has returned to the movement start position over the rear clamper 37R as a result of sliding on the first pattern-formed area R1 of the mask 13, the front squeegee 52F is elevated and a standby state is established.

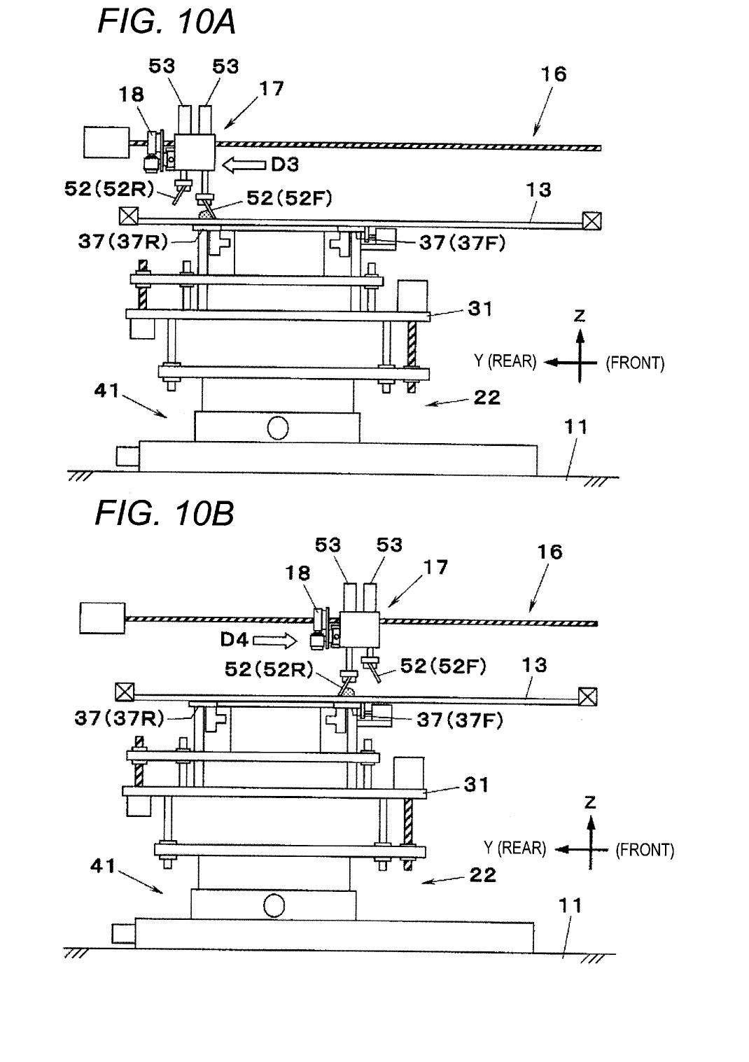

On the other hand, to form a paste print on the board 2 using the second pattern PT2 by squeegeeing, first, the front squeegee 52F is lowered from over the region Rm between the first pattern-formed area R1 and the second pattern-formed area R2 until its bottom end comes into contact with the mask 13 in the region Rm where the front clamper 37F is in contact with the mask 13. Then the front squeegee 52F is moved backward (indicated by arrow D3 in FIG. 10A) with the above contact position as a movement start position. When the front squeegee 52F has reached a position over the rear clamper 37R as a result of sliding on the second pattern-formed area R2 of the mask 13, the front squeegee 52F is elevated and the rear squeegee 52R is lowered until its bottom end comes into contact with the mask 13 over the rear clamper 37R is in contact with the mask 13. Then the rear squeegee 52R is moved forward (indicated by arrow D4 in FIG. 10B) from the above contact position. When the rear squeegee 52R has returned to the movement position over the front clamper 37F as a result of sliding on the second pattern-formed area R2 of the mask 13, the rear squeegee 52R is elevated and a standby state is established.

As described above, in the screen printer 5 according to the first embodiment, when a print of paste Pst should be formed on a board 2 that is in contact with the first pattern-formed area R1 using the first pattern PT1, the print head 17 is operated so as to reciprocate across the first pattern-formed area R1 in the Y-axis direction, that is, to move from a movement start position that is a position in the region Rm between the first pattern-formed area R1 and the second pattern-formed area R2 on the mask 13 and return to the movement start position. When a print of paste Pst should be formed on a board 2 that is in contact with the second pattern-formed area R2 using the second pattern PT2, the print head 17 is operated so as to reciprocate across the second pattern-formed area R2 in the Y-axis direction, that is, to move from the above movement start position and return to the movement start position.

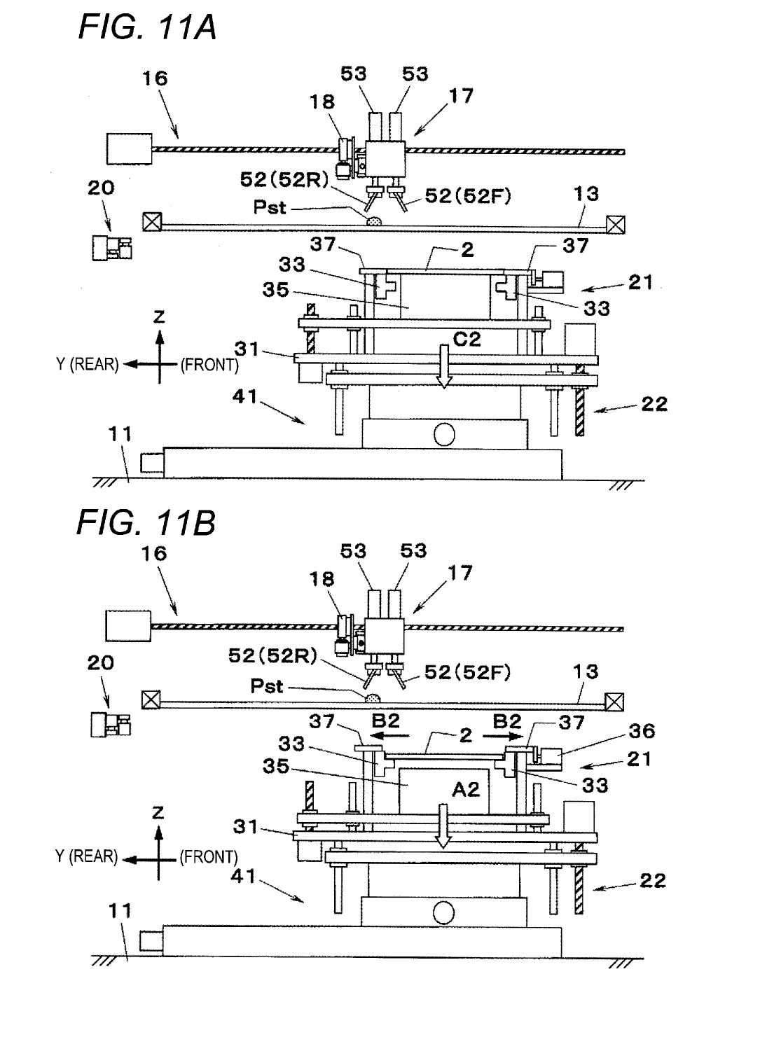

When a print of paste Pst has been formed on the board 2 by causing paste Pst to pass through the pattern of the mask 13 by reciprocating the squeegees 52, the control device 60 controls the second elevation motor 42 so that it lowers the elevation plate 31 (indicated by arrow C2 in FIG. 11A) and thereby separates the board 2 from the mask 13 (plate releasing; see FIG. 11A). Thus, the screen printing operation for the one board 2 is completed.

Upon completion of the screen printing of the one board 2, the control device 60 controls the clamper drive motor 36 so that it opens the clampers 37 (indicated by arrows B2 in FIG. 11B) and controls the first elevation motor 34 so that it lowers the support member 35 (indicated by arrow A2 in FIG. 11B), whereby the board 2 is placed on the conveyors 33 (see FIG. 11B). Then, the control device 60 causes the carry-out conveyor 15 to be placed at a position opposing the board holding unit 21 (see FIG. 7D), and causes the conveyors 33 and the carry-out conveyor 15 to operate in link with each other so that the board 2 is carried out from the screen printer 5 to another, downstream machine (component mounter 6) (see FIG. 7E). When the board 2 has been carried out, the control device 60 judges whether there exists another board 2 to be subjected to screen printing. If judging that there exists another board 2 to be subjected to screen printing, the control device 60 has the other board 2 carried in using the carry-in conveyor 14. If judging that there is no board 2 to be subjected to screen printing, the control device 60 finishes the process.

In the above-described screen printing operation, a print of paste Pst is formed on a board 2 as the print head 17 reciprocates across the first pattern-formed area R1 or the second pattern-formed area R2 starting from the movement start position that is in the region Rm between the first pattern-formed area R1 and the second pattern-formed area R2 on the mask 13. Therefore, for example, paste Pst exits at the movement start position (i.e., the start position of a reciprocation) not only when a print of paste Pst is to be formed on another board 2 using the pattern PT1 after a print of paste Pst has been formed on a board 2 but also when a print of paste Pst is to be formed on another board 2 using the pattern PT2. Therefore, wasteful use of the paste Pst on the mask 13 can be avoided and hence the amount of paste Pst that is discarded wastefully can be reduced. Furthermore, since the paste Pst on the mask 13 is returned to the region Rm between the first pattern-formed area R1 and the second pattern-formed area R2 on the mask 13 when a printing operation has been completed, printing operations can be started immediately even if different kinds of boards 2 are carried in in random order (i.e., a printing operation can be started immediately irrespective of whether a board 2 is brought into contact with the first pattern-formed area R1 or the second pattern-formed area R2).

As shown in FIG. 1, the component mounter 6 is a two-lane component mounter equipped with two board conveying lanes. The component mounter 6 is equipped with two board conveying lanes 72, that is, a first board conveying lane 72a and a second board conveying lane 72b, disposed on a stage 71, plural parts feeders 73 as parts supply units, and two mounting heads 75 which is moved by a head moving mechanism 74 which is an XY robot. The first board conveying lane 72a receives, from the carry-out conveyor 15, a board 2 on which a paste print has been formed by the screen printer 5 using the first pattern PT1 and carries it in. The second board conveying lane 72b receives, from the carry-out conveyor 15, a board 2 on which a paste print has been formed by the screen printer 5 using the second pattern PT2 and carries it in. Each of the first board conveying lane 72a and the second board conveying lane 72b positions a board 2 that has been received from the screen printer 5 at a prescribed position. Each of the two mounting heads 75 picks up a component 3 supplied from the associated parts feeder 73 and mounts it on the board 2 that has been positioned by the associated one of the first board conveying lane 72a and the second board conveying lane 72b. When the mounting of the component on the board 2 has been completed, the board conveying lane 72 that positioned the board 2 is operated, whereby the board 2 is carried out to the outside (a downstream machine).

As described above, in the screen printer 5 according to the first embodiment, a print of paste Pst is formed as the print head 17 reciprocates across the first pattern-formed area R1 or the second pattern-formed area R2 starting from the movement start position that is in the region Rm between the first pattern-formed area R1 and the second pattern-formed area R2 on the mask 13. And the single print head 17 serves as both of a print head for printing with the first pattern PT1 and printing with the second pattern PT2. This makes it possible to perform, in parallel, with a simple configuration, printing on plural kinds of boards 2 to accommodate the component mounter 6 on the downstream process side. Furthermore, since the print head 17 reciprocates, that is, moves from the movement start position that is in the region Rm between the first pattern-formed area R1 and the second pattern-formed area R2 and returns to the original position (movement start position), residual paste Pst can be used for the next printing irrespective of whether printing has been performed using the first pattern PT1 or the second pattern PT2. Therefore, the amount of paste Pst wasted is reduced and hence the cost of printing operations can be reduced accordingly. Still further, since the paste Pst on the mask 13 is returned to the region Rm between the first pattern-formed area R1 and the second pattern-formed area R2 on the mask 13 when a printing operation has been completed, printing operations can be started immediately even if different kinds of boards are carried in in random order (i.e., a printing operation can be started immediately irrespective of whether a board 2 is brought into contact with the first pattern-formed area R1 or the second pattern-formed area R2).

In the screen printer 5 according to the first embodiment, the carry-in conveyor 14 (board carry-in unit) which receives a board 2 that has been conveyed from outside the screen printer 5 and transfers it to the board holding/moving mechanism 12 and the carry-out conveyor 15 (board carry-out unit) which receives a board 2 on which a print of paste Pst has been formed by the print head 17 from the screen printer 5 and carries it to outside the screen printer 5 are each disposed so as to be movable in the Y-axis direction (i.e., the arrangement direction of the first pattern-formed area R1 and the second pattern-formed area R2 in the screen printer 5). Therefore, it suffices to employ only one carry-in conveyor 14 and only one carry-out conveyor 15, which also contributes to the simplification of the configuration.

### Second Embodiment

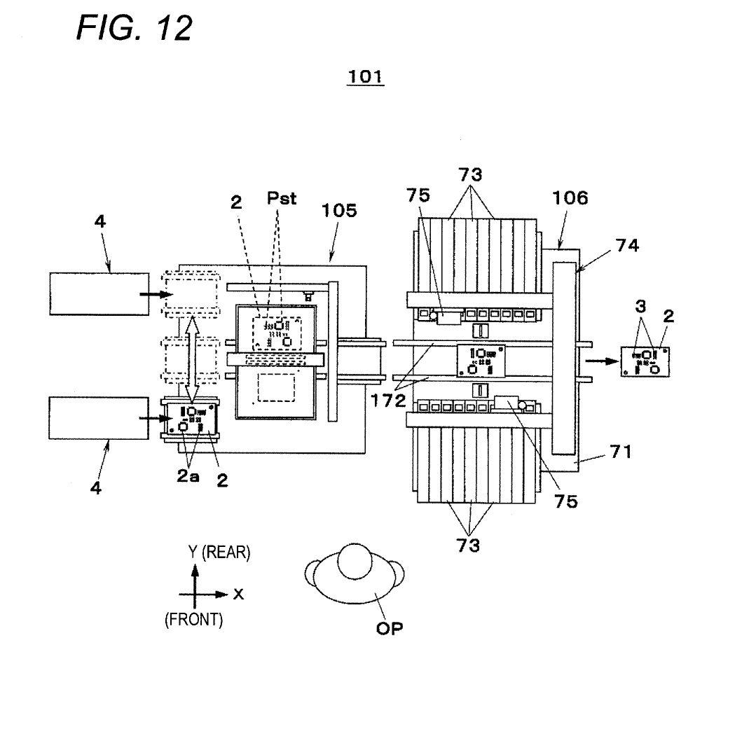

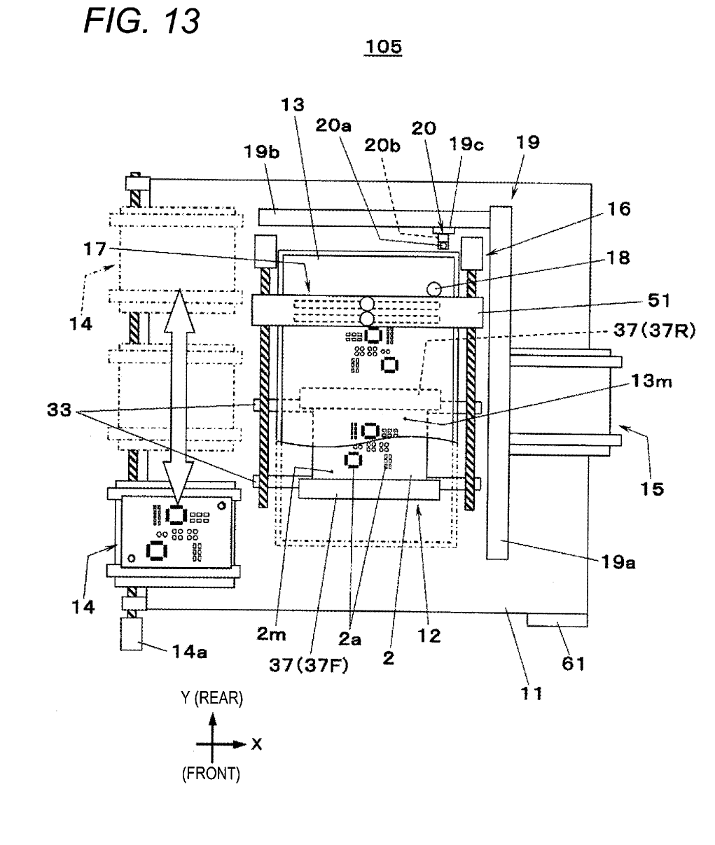

Next, a second embodiment of the invention will be described. FIG. 12 shows a component mounting line 101 according to the second embodiment of the invention. Similar to the component mounting line 1 according to the first embodiment, the component mounting line 101 includes a screen printer 105 and a component mounter 106. In FIGS. 12 and 13, constituent elements of the screen printer 105 having the same ones in the screen printer 5 according to the first embodiment are given the same reference symbols as the latter. In FIG. 12, constituent elements of the component mounter 106 having the same ones in the component mounter 6 used in the first embodiment are given the same reference symbols as the latter.

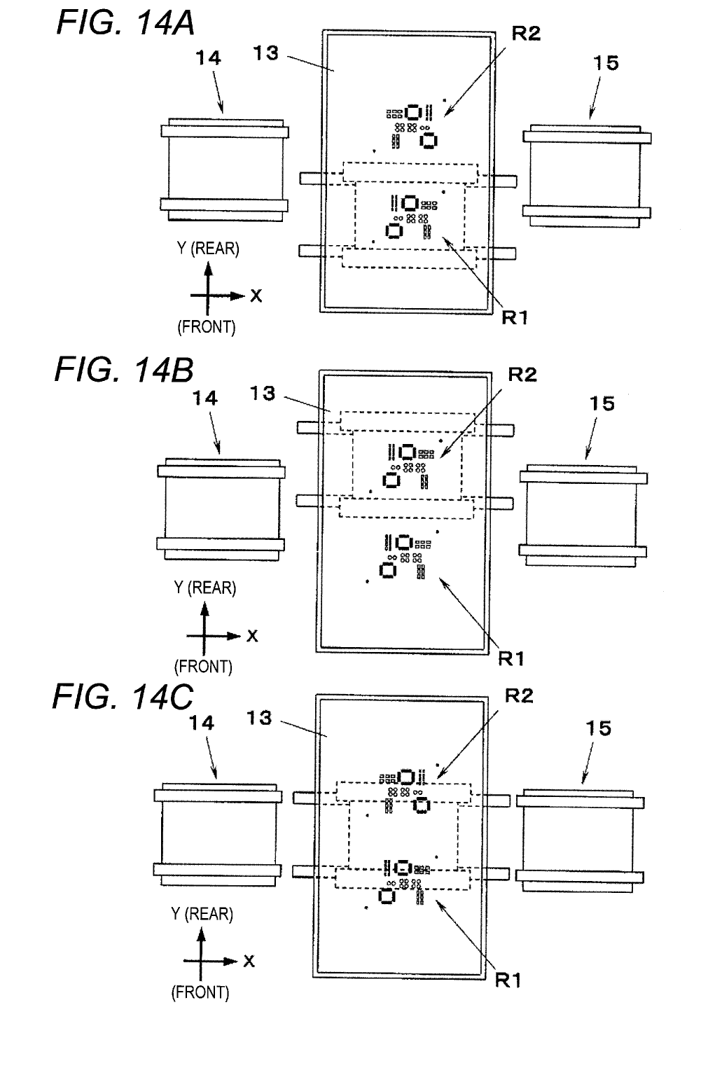

The screen printer 105 according to the second embodiment is configured basically in the same manner as the screen printer 5 according to the first embodiment, and different from the latter in the following points. In the screen printer 105 according to the second embodiment, the board holding unit 21 can be placed at an intermediate position (see FIG. 14C) between the first position (see FIG. 14A) located under the first pattern-formed area R1 and the second position (see FIG. 14B) located under the second pattern-formed area R2, as well as at the first position and the second position. The board holding unit 21 receives a board 2 from the carry-in conveyor 14 at the intermediate position. The board 2 is then clamped by the clampers 37 and moved to the first position or the second position, where the board 2 is brought into contact with the mask 13.

As shown in FIG. 12, the component mounter 106 used in the second embodiment is a one-lane component mounter which is equipped with only one board conveying lane 172 which is disposed at a position corresponding to the intermediate position of the screen printer 105. Therefore, as shown in FIG. 13, the carry-out conveyor 15 is fixed at a position corresponding to the intermediate position. Irrespective of whether screen printing has been performed at the first position or the second position, the board holding unit 21 is necessarily moved to the intermediate position and transfers the board 2 to the carry-out conveyor 15. The carry-out conveyor 15 carries out the board 2 received from the board holding unit 21 to the board conveying lane 172 of the component mounter 106. The component mounter 106 carries in the board 2 with the board conveying lane 172 and mounts a component 3 on the board 2 by means of the mounting heads 75.

As described above, in the screen printer 105 according to the second embodiment, the board holding unit 21 can be moved selectively to the first position corresponding to the first pattern-formed area R1, the second position corresponding to the second pattern-formed area R2, or the intermediate position which is located between the first position and the second position and serves as a board reception/output position where a board 2 is received from the carry-in conveyor 14 (board carry-in unit) and transferred to the carry-out conveyor 15 (board carry-out unit).

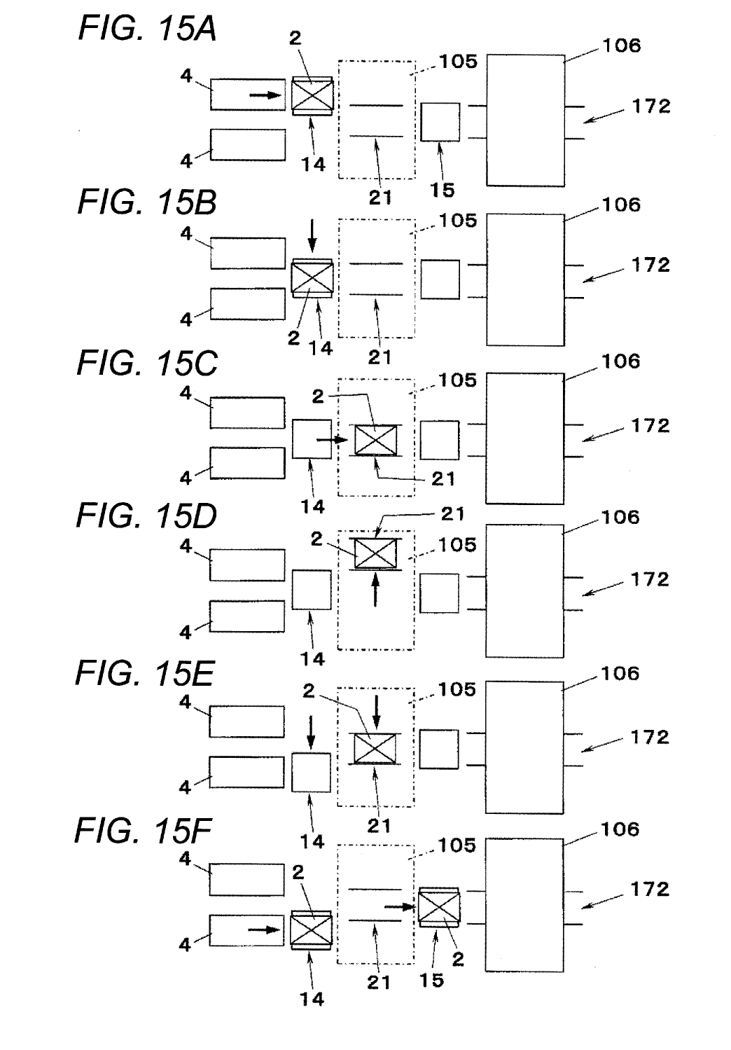

Next, a procedure according which the screen printer 105 performs a screen printing operation will be described with reference to FIGS. 15A-15F. When a board 2 is to be output from one of the two board supply units 4, the control device 60 causes the carry-in conveyor 14 to be moved to such a position as to be opposed to the board supply unit 4 that is going to output the board 2 (see FIG. 15A). The control device 60 causes the carry-in conveyor 14 which has received the board 2 to such a position as to be opposed to the board holding unit 21 located at the intermediate position (see FIG. 15B), causes the board 2 to be carried in to the board holding unit 21 by having the carry-in conveyor 14 and the conveyors 33 of the board holding unit 21 (located at the intermediate position) to operate in link with each other (see FIG. 15C), and causes the board 2 to be positioned at the clamping position and clamped (held) by the clampers 37.

When the board 2 has been held by the board holding unit 21, the control device 60 causes the board holding unit 21 to be moved to the first position or the second position (see FIG. 15D). Then the control device 60 causes the board 2 to be brought into contact with the mask 13 according to the same procedure as in the first embodiment through shooting of the mask-side marks 13m and the board-side marks 2m by the camera unit 20. FIG. 15D shows a state that the board holding unit 21 is placed at the second position.

When the board 2 has been brought into contact with the mask 13, the control device 60 causes squeegeeing of paste Pst using the print head 17. In the screen printer 105 according to the second embodiment, as in the screen printer 5 according to the first embodiment, the print head 17 is operated in the following manner. To form a print of paste Pst on the board 2 being in contact with the first pattern-formed area R1 using the first pattern PT1, the print head 17 starts from a movement start position which is a position in the region Rm located on the mask 13 between the first pattern-formed area R1 and the second pattern-formed area R2, reciprocates across the first pattern-formed area R1 in the Y-axis direction, and returns to the movement start position (see FIGS. 9A and 9B). On the other hand, to form a print of paste Pst on the board 2 being in contact with the second pattern-formed area R2 using the second pattern PT2, the print head 17 starts from a movement start position which is a position in a region Rm located on the mask 13 between the first pattern-formed area R1 and the second pattern-formed area R2, reciprocates across the second pattern-formed area R2 in the Y-axis direction, and returns to the movement start position (see FIGS. 10A and 10B).

When a print of paste Pst has been formed on the board 2 by causing paste Pst to pass through the pattern of the mask 13, the control device 60 causes the board 2 to be separated from the mask 13 (plate releasing) according to the same procedure as in the first embodiment and causes the board holding unit 21 to be moved to the intermediate position (see FIG. 15E). Then the control device 60 causes the board 2 to be placed on the conveyors 33, causes the board 2 to be transferred to the carry-out conveyor 15 by having the conveyors 33 and the carry-out conveyor 15 to operate in link with each other (see FIG. 15F), and causes the carry-out conveyor 15 to carry out the board 2 to the board conveying lane 172, according to the same procedure as in the first embodiment.

The component mounter 106 receives (takes in) a board 2 on which printing has been performed by the screen printer 105 using the first pattern PT1 or the second pattern PT2, from the carry-out conveyor 15 by means of the board conveying lane 172. The board conveying lane 172 positions the received board 2 at a prescribed position. Each of the two mounting heads 75 picks up a component 3 which is supplied by the parts feeders 73 and mounts the component 3 on the board 2 which has been positioned by the board conveying lane 172. In this operation, a control device (not shown) of the component mounter 106 judges a kind of the received board 2 (i.e., whether printing has been performed on it using the first pattern PT1 or the second pattern PT2) and causes the mounting heads 75 to mount a component 3 that is suitable for the kind of the received board 2 (board-mixed mounting). Upon completion of the mounting of the component 3 on the board 2, the control unit activates the board conveying lane 172 to carry out the board 2 to the outside (a downstream process).

As described above, also in the screen printer 105 according to the second embodiment, the print head 17 forms a print of paste Pst on the board 2 by starting from the movement start position in the region Rm which is located between the first pattern-formed area R1 and the second pattern-formed area R2 and reciprocates across the first pattern-formed area R1 or the second pattern-formed area R2. That is, the single print head 17 serves as both of a print head for printing using the first pattern PT1 and a print head for printing using the second pattern PT2. As such, the screen printer 105 according to the second embodiment provides the same advantage as that of the component mounting line 101 according to the first embodiment, in which parallel printing on plural kinds of boards that are compatible with the component mounter 106 installed downstream can be realized with a simple configuration.

Furthermore, since the print head 17 reciprocates, that is, starts from the movement start position in the region Rm which is located between the first pattern-formed area R1 and the second pattern-formed area R2 and returns to the original position (movement start position), residual paste Pst can be used for the next printing irrespective of whether printing has been performed using the first pattern PT1 or the second pattern PT2. Therefore, the amount of paste Pst wasted is reduced and hence the cost of printing operations can be reduced accordingly, which is also the same advantage as provided by the component mounting line 101 according to the first embodiment. Still further, since the paste Pst on the mask 13 is returned to the region Rm which is located between the first pattern-formed area R1 and the second pattern-formed area R2 on the mask 13 when a printing operation has been completed, printing operations can be started immediately even if different kinds of boards are carried in in random order (i.e. a printing operation can be started immediately irrespective of whether a board 2 is brought into contact with the first pattern-formed area R1 or the second pattern-formed area R2). This is also the same advantage as provided by the component mounting line 101 according to the first embodiment.

The two-lane component mounter 6 used in the first embodiment can increase the board manufacturing efficiency of the component mounting line 1 as a whole because component mounting is performed independently in the two lanes. On the other hand, the component mounter 106 according to the second embodiment allows the component mounting line 101 as a whole to perform low-cost board manufacture that is suitable for manufacture of boards in small numbers and space saving because the one-lane component mounter 106 performs board-mixed mounting in the single lane. It becomes possible to accommodate various board manufacturing modes as mentioned above by determining whether to use a two-lane component mounter or a one-lane component mounter and use the screen printer 5 according to the first embodiment and the screen printer 105 according to the second embodiment while selecting between them properly.

The embodiments of the invention provides a screen printer and a component mounting line which can perform printing operations on plural kinds of boards in parallel with a simple configuration while enabling reduction of the amount of paste wasted.

What is claimed is:

1. A screen printer comprising:
a mask having a first area formed with a first pattern and a second area formed with a second pattern such that the first area and the second area are arranged in an arrangement direction;
a board holding/moving mechanism which is movable in the arrangement direction under the mask, and which comprises a board holding unit which holds a board so as to allow the board to selectively contact one of the first area and the second area by moving the board holding unit; and
a print head which forms a past printing on the board through the mask, and which is movable on the mask in the arrangement direction,
wherein when a paste print is formed on the board contacting the first area by using the first pattern, the print head moves in the arrangement direction from a start position located between the first area and the second area to the first area and then returns to the start position, and
wherein when a paste print is formed on the board contacting the second area by using the second pattern, the print head moves in the arrangement direction from the start position to the second area and then returns to the start position.

2. The screen printer according to claim 1, further comprising:
a board carry-in unit which is movable in the arrangement direction, and which transfers a board carried in from an upstream machine to the board holding/moving mechanism; and
a board carry-out unit which is movable in the arrangement direction, and which receives the board on which a paste print has been formed by the print head from the board holding/moving mechanism and carries out the board to a downstream machine.

3. A component mounting line comprising:
the screen printer according to claim 1; and
a component mounter which mounts a component on the board on which the paste print has been formed by the screen printer;
wherein the component mounter comprises a first board conveying lane and a second board conveying lane which are arranged in the arrangement direction,
wherein the first board conveying lane carries in the board on which the paste print has been formed using the first pattern, and
wherein the second conveying lane carries in the board on which the paste print has been formed using the second pattern.

4. The screen printer according to claim 1, further comprising:
a board carry-in unit which is movable in the arrangement direction, and which transfers a board carried in from an upstream machine to the board holding/moving mechanism; and
a board carry-out unit which receives the board on which the paste print has been formed by the print head from the board holding/moving mechanism, and which carries out the board to a downstream machine,
wherein the board holding/moving mechanism is movable among a first position corresponding to the first area, a second position corresponding to the second area, and a third position which is located between the first position and the second position and at which the board is received from the board carry-in unit and transferred to the board carry-out unit.

5. A component mounting line comprising:
the screen printer according to claim 1; and
a component mounter which mounts a component on the board on which the paste print has been formed by the screen printer; and
wherein the component mounter comprises a board conveying lane which carries in the board on which the paste print has been formed by using the first pattern and the board on which the paste print has been formed by using the second pattern.
